(19) United States
(12) Patent Application Publication
(10) Pub. No.: US 2004/0263216 A1
(43) Pub. Date: Dec. 30, 2004

(54) Integrated circuit having a voltage monitoring circuit and a method for monitoring an internal burn-in voltage

(76) Inventors: Manfred Proll, Dorfen (DE); Stephan Schroder, Munchen (DE); Johann Pfeiffer, Ottobrunn (DE); Jurgen Auge, Unterhaching (DE)

Correspondence Address: GERO G. McCLELLAN, MOSER, PATTERSON & SHERIDAN, L.L.P., Suite 1500, 3040 Post Oak Blvd., Houston, TX, 77056, US

(21) Appl. No.: 10/835,190

(22) Filed: Apr. 29, 2004

(30) Foreign Application Priority Data
Apr. 29, 2003 (DE) DE 103 19 157.7

(51) Int. Cl. H03K 5/153

(52) U.S. Cl. 327/78

(57) ABSTRACT

Integrated circuit having a voltage monitoring circuit and a method for monitoring an internal burn-in voltage. One embodiment provides an integrated circuit having a voltage monitoring circuit for monitoring an internal burn-in voltage provided during the burn-in operation of the integrated circuit, wherein a reference voltage is provided, which defines a lower limit for the burn-in voltage, wherein a comparison voltage dependent on the internal burn-in voltage and the reference voltage are applied to a comparator device to carry out a threshold value comparison of the internal burn-in voltage with the reference voltage. A burn-in signal may be output at an output of the comparator device so that the burn-in signal can be used to ascertain whether the burn-in voltage lies below or above a voltage threshold defined by the reference voltage.

### CROSS-REFERENCE TO RELATED APPLICATIONS

This application claims foreign priority benefits under 35 U.S.C. §119 to co-pending German patent application number DE 103 19 157.7, filed Apr. 29, 2003. This related patent application is herein incorporated by reference in its entirety.

### BACKGROUND OF THE INVENTION

1. Field of the Invention

The invention relates to an integrated circuit having a voltage monitoring circuit for monitoring an internal burn-in voltage provided during the burn-in operation of the integrated circuit. The invention furthermore relates to a method for monitoring a burn-in voltage provided during a burn-in operation.

1. Description of the Related Art

In integrated circuits, it is possible for so-called early failures to occur when the integrated circuit is used in the final apparatus, on account of errors and parameter alterations in the fabrication sequence and, in particular, on account of small feature sizes with minimal oxide thicknesses and interconnect spacings. Early failures arise if, in the case of an integrated module tested as free of errors, an error occurs as a result of the temperature and current loading during operation as early as in the initial usage.

The frequency of such early failures is reduced in integrated circuits by means of an artificial pre-ageing or a so-called burn-in. The pre-ageing allows the manufacturer of the integrated circuit to make a statement about the maximum occurring early failure rate in the final apparatus, in the form of a dpm specification (devices per million) or FIT specification (failure in time=corresponds to one failure per 10⁹ module operating hours).

In order that the pre-ageing of the integrated circuit can be carried out efficiently and cost-effectively, it is necessary to achieve a high acceleration factor during the burn-in. Said acceleration factor defines what effective burn-in time corresponds to an equivalent module operating duration. The acceleration factor is generally set by the parameters which are critical for the stress, such as, e.g., the temperature and the operating voltage. The burn-in is then carried out by increasing the temperature and applying an increased operating voltage compared with the specification-conforming operating voltage, said increased operating voltage being known as the burn-in voltage.

In order to ensure identical acceleration factors for the pre-ageing for all the integrated circuits in the burn-in operation, it is necessary to monitor the parameters (temperature, voltage and the like)—defining the component stress—of each individual module during the burn-in operation. The modules which, for specific reasons, are not tested under the predetermined stress conditions but rather under reduced-stress conditions during the burn-in operation have a pre-ageing that is less than assumed and thus constitute an increased quality risk.

The temperature during the burn-in operation is a variable that is relatively simple to monitor. The burn-in operation is carried out in a heated environment, the relevant modules assuming the temperature of the environment.

However, the burn-in voltage made available to the module to be tested, which is increased compared with the normal operating voltage, is more difficult to monitor. Monitoring of the internal burn-in voltage is important, however, since the burn-in voltage is the dominant parameter of the ageing acceleration during the burn-in operation. However, monitoring the burn-in voltage present within the integrated module is difficult on account of the inaccessibility of the integrated circuit from the outside. Although it is known what external voltage is applied as burn-in voltage during the burn-in operation to the integrated module to be pre-aged, this generally does not correspond to the internal burn-in voltage of the module, and the internal burn-in voltage is not known exactly because of voltage drops across the line resistances or the like and because the current that flows generally cannot be set exactly.

### SUMMARY OF THE INVENTION

It is an object of the present invention to provide an integrated circuit in which the burn-in voltage provided internally can be monitored during the burn-in operation.

A first aspect of the present invention provides an integrated circuit having a voltage monitoring circuit for monitoring an internal burn-in voltage provided during the burn-in operation of the integrated circuit. In this case, a reference voltage is provided, which defines a lower limit for the internal burn-in voltage. A comparison voltage dependent on the internal burn-in voltage and the reference voltage are applied to a comparator device, in order to carry out a threshold value comparison of the internal burn-in voltage with the reference voltage. It is possible for a burn-in signal to be output at an output of the comparator device, so that the burn-in signal can be used to ascertain whether the burn-in voltage lies below or above a voltage threshold defined by the reference voltage.

The integrated circuit according to the invention has the advantage that a voltage monitoring circuit connected to an internal burn-in voltage can be used to directly check the potential of the internal burn-in voltage. Since the internal burn-in voltage essentially depends on the line, module and socket contact resistances, on the current required by the integrated circuit and the externally applied burn-in voltage, the burn-in voltage present internally cannot be determined exactly on the basis of the externally applied burn-in voltage.

The voltage monitoring circuit now carries out, within the integrated circuit, a comparison between the internal burn-in voltage and a reference voltage provided, so that it is possible to ascertain on the basis of the burn-in signal whether the potential of the internal burn-in voltage is above or below the reference voltage. Consequently, by means of the burn-in voltage, it is possible to ascertain from the outside whether, during the burn-in operation, the internal burn-in voltage lies above a voltage threshold prescribed by the reference voltage. The voltage threshold specifies whether the internal burn-in voltage, during the burn-in operation, is equal to or greater than the potential necessary for a specification-conforming pre-ageing process.

In one embodiment, a test circuit is connected to the comparator device to receive the burn-in signal. The test circuit is configured to generate an error signal during a test operation of the integrated circuit that proceeds during the burn-in operation. The error signal indicates whether a functional error of the integrated circuit is present. The test circuit generates an error signal indicating a functional error if the burn-in signal indicates that the internal burn-in voltage lies below the reference voltage. In this way, it is possible, on the one hand, to save a terminal of the integrated circuit which would be necessary for monitoring the burn-in signal. This is achieved in that the burn-in signal acts on a test circuit in such a way that, during the test, an error signal which indicates a functional error of the integrated circuit is always generated if the internal burn-in voltage falls below the reference voltage.

The test circuit may comprise a switching device, which receives the burn-in signal as control signal and applies the error signal indicating a functional error to an output of the test circuit.

A voltage conversion circuit may be provided to generate the comparison voltage from the internal burn-in voltage with the aid of a voltage divider having a first resistor unit and having a second resistor unit. A comparison voltage proportional to the internal burn-in voltage is made available in this way. In this case, the voltage conversion circuit may be connected to the comparator device via a low-pass filter circuit to filter out momentary voltage changes in the internal burn-in voltage. Such momentary voltage changes may occur, for example, on account of switching operations.

Furthermore, a voltage generator circuit may be provided to generate the reference voltage from the internal burn-in voltage with the aid of a zener diode and a further voltage divider having a third resistor unit and having a fourth resistor unit. What can be achieved in this way by reduction of the reference voltage potential and the comparison voltage potential is that the comparator device can be constructed more simply since comparison voltage potential and reference voltage potential are at a low potential and, consequently, at an optimum operating point. Furthermore, it is possible with the aid of the zener diode to generate a relatively exact voltage which exhibits only little dependence on external influences and is made available to the comparator device in proportionally altered fashion with the aid of the further voltage divider.

Since various integrated circuits are embodied using different technologies, the burn-in operations are carried out with different parameters and different stress conditions. Thus, the burn-in voltages which are to be used and are applied to the integrated module to be tested differ considerably from one another, depending on the technology. In order to use basically the same voltage monitoring circuit, it may be provided that the resistance of the fourth resistor unit is adjustable.

In one embodiment, the fourth resistor unit is formed with a first and a second resistance path, which are arranged in parallel with one another, wherein it is possible for the first and second resistance path to be switched on or off in accordance with programming. The resistance paths in each case may have a resistor and a fuse element, which are connected in series, in order to switch off the resistance path by severing the fuse element. In this way, the voltage threshold above which the internal burn-in voltage must lie can be defined by setting the reference voltage. The reference voltage can be set by severing laser fuse elements during a laser trimming process. Since such a laser trimming process is usually carried out in integrated circuits after the fabrication thereof, to set specific component-dependent parameters or, in memory circuits, to replace defective memory areas by redundant memory areas, the severing of laser fuses during the laser trimming process is not associated with a significant additional time expenditure.

A further aspect of the present invention provides a method for monitoring an internal burn-in voltage provided during a burn-in operation in an integrated circuit. A reference voltage is provided, which defines a lower limit for the burn-in voltage. A comparison voltage dependent on the internal burn-in voltage and the reference voltage are compared with one another to generate a burn-in signal which can be used to ascertain whether the burn-in voltage lies below or above a voltage threshold prescribed by the reference voltage.

As already described above, the method according to one embodiment of the invention makes it possible to check the internal burn-in voltage of the integrated circuit by comparison with a reference voltage and to ascertain with the aid of a burn-in signal whether the burn-in operation is being carried out under the necessary stress conditions.

An error signal may be generated during a test operation that proceeds during the burn-in operation. The error signal indicates whether a functional error of the integrated circuit is present. An error signal that indicates a functional error is generated if the burn-in signal indicates that the comparison voltage defined by the internal burn-in voltage lies below the reference voltage. What can thus be achieved in a simple manner is that the burn-in signal is converted into an error signal. If the integrated circuit is tested during the burn-in operation, a burn-in signal which indicates that the comparison voltage defined by the internal burn-in voltage lies below the reference voltage alters the error signal such that a functional error is indicated even when no functional error has occurred. Such an error signal then indicates that the burn-in operation has not been carried out properly and that the specifications with regard to the early failure rate thus cannot be complied with.

### BRIEF DESCRIPTION OF THE DRAWINGS

A preferred embodiment of the invention is explained in more detail below with reference to the accompanying drawings, in which:

FIG. 1 is a circuit diagram illustrating an integrated circuit in accordance with a first embodiment of the invention; and

FIG. 2 is a circuit diagram illustrating a voltage monitoring circuit for an integrated circuit in accordance with a further embodiment of the invention.

### DETAILED DESCRIPTION OF THE PREFERRED EMBODIMENT

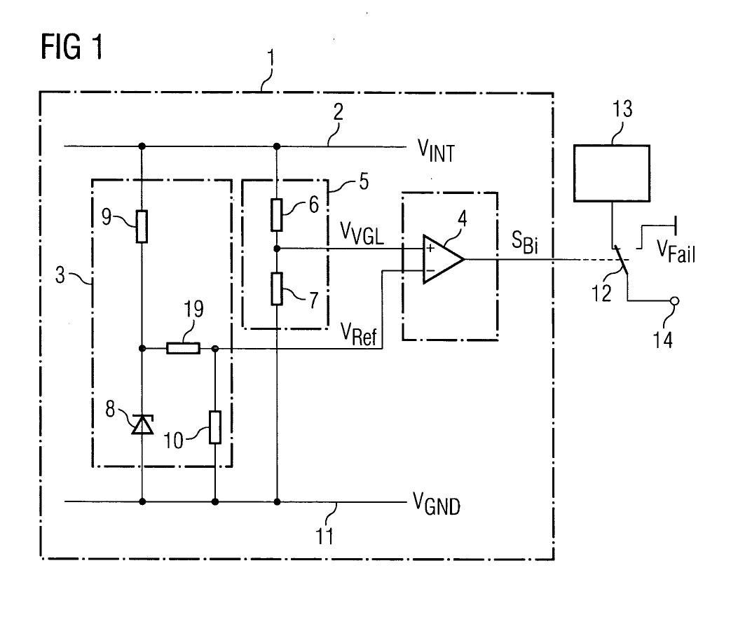

FIG. 1 illustrates an integrated circuit having a voltage monitoring circuit 1. The voltage monitoring circuit 1 serves to monitor an internal burn-in voltage V_{INT} provided on a first supply voltage line 2 during a burn-in operation of the integrated circuits.

During the burn-in operation, an external burn-in voltage is applied to the module to be pre-aged. The internal burn-in voltage of an individual component which is established during the burn-in operation may, for various reasons, not correspond to the desired value set. Generally, two main cases can be distinguished, and the cases typically result from the construction of the burn-in system and from the construction of the individual integrated circuit. Thus, the burn-in sockets of the burn-in system into which the modules that are to be pre-aged are inserted have a high degree of wear and poor contact resistances after a number of burn-in cycles at elevated temperature. This also applies to the supply voltage terminals of the integrated circuits. As a result, socket-specific supply voltage drops may occur at the integrated circuit. Buffer capacitances are usually fitted at the socket and age rapidly on account of the elevated temperatures. The buffer capacitances may regularly have short circuits which influence the voltage supply of the integrated component.

In addition, due to internal short circuits on account of the stress condition during the burn-in operation, high currents may flow on the supply voltage lines, which can lead to voltage drops on the voltage supply lines. Furthermore, overloaded supply voltages likewise may lead to a drop in the burn-in voltage present internally.

With the aid of a voltage generator circuit 3, a reference voltage potential V_{Ref} is applied to an inverting input of a comparator device 4. With the aid of a voltage converter circuit 5, the internal burn-in voltage V_{INT} is reduced and a resulting comparison potential V_{VGL} is applied to the noninverting input of the comparator device 4.

The reference voltage potential V_{Ref} is chosen to prescribe a threshold with regard to the comparison potential V_{VGL}. If the comparison potential V_{VGL} falls below the threshold prescribed by the reference voltage potential, then the internal burn-in voltage V_{INT} has fallen below a voltage value prescribed by the specification, and the required specifications for the burn-in voltage have not been complied with during the burn-in operation. A burn-in signal S_{Bi} can be tapped off at an output of the comparator device 4.

The comparison potential V_{VGL} is provided by the voltage converter circuit 5, which is formed as a voltage divider. The voltage divider has a first resistor unit 6 and a second resistor unit 7. The resistances of the first and second resistor units 6, 7 are chosen to divide the internal burn-in voltage V_{INT} into a voltage range which ensures a good operating point of the comparator device 4.

The voltage generator circuit 3 serves to provide the reference potential V_{Ref}. For this purpose, the voltage generator circuit 3 has a zener diode 8 connected in series with a third resistor unit 9 between the first supply voltage line 2 and a second supply line 11, which is connected to a low supply potential. A voltage divider having a fourth resistor unit 10 and a fifth resistor unit 19 is arranged in parallel with the zener diode 8. Such an arrangement between the first supply line 2 and the second supply line 11 provides a reference potential V_{Ref} which is generally independent of the potential of the internal burn-in voltage V_{INT} present. The potential of the reference voltage V_{Ref} is essentially prescribed by the embodiment of the zener diode 8 and also the voltage divider of the voltage generator circuit 3.

The voltage dividers of the voltage converter circuit 5 and also the voltage generator circuit 3 are dimensioned such that the reference potential V_{Ref} prescribes the threshold above which the internal burn-in voltage V_{INT} must lie, in accordance with the following formula:

$${V}_{INT} \geq \frac{( R1 + R2 )}{R2} \cdot {V}_{Ref}$$

where R1 corresponds to the resistance of the first resistor unit 6 and R2 corresponds to the resistance of the second resistor unit 7.

The burn-in signal S_{Bi} is present at the output of the comparator device 4. The burn-in signal S_{Bi} generally corresponds to the comparison value and is at a logic “1” if the burn-in voltage V_{INT} is greater than the threshold prescribed by the reference potential V_{Ref}. The burn-in signal S_{Bi} is at a logic “0” if the internal burn-in voltage V_{INT} is less than the threshold prescribed by the reference potential V_{Ref}.

The burn-in signal S_{Bi} is connected to a switching device 12. A test circuit 13 is furthermore provided, which tests the functionality of the integrated circuit during the burn-in operation. The test circuit 13 generates an error signal which specifies whether a functional error of the integrated circuit has occurred.

In the case of a memory circuit, test data may be written successively to the memory areas of the memory circuit, and the data are subsequently read out again. Through a comparison of the data written in and read out, an error is ascertained in the event of differences. If the internal burn-in voltage V_{INT} lies above the value prescribed by the reference potential V_{Ref}, then the burn-in signal S_{Bi} is present with a logic “1” at the output of the comparator device 4. In this case, the switching device 12 is switched in such a way that an output of the tester device 13 is connected to an output terminal 14 of the integrated circuit.

If a logic “0” is present at the output of the comparator device 4, then the internal burn-in voltage does not correspond to the prescribed specifications and the necessary stress condition has not been reached. In this case, the switching device 12 switches in such a way that the output terminal 14 of the integrated circuit is connected to an error potential V_{Fail}, which specifies that an error has occurred in the integrated circuit. The error potential V_{Fail} generally corresponds to the potential with which the error signal indicates on the test circuit 13 that a functional error has occurred. However, the error potential V_{Fail} may also assume other potentials which make it possible to ascertain an error of the internal burn-in voltage V_{INT}.

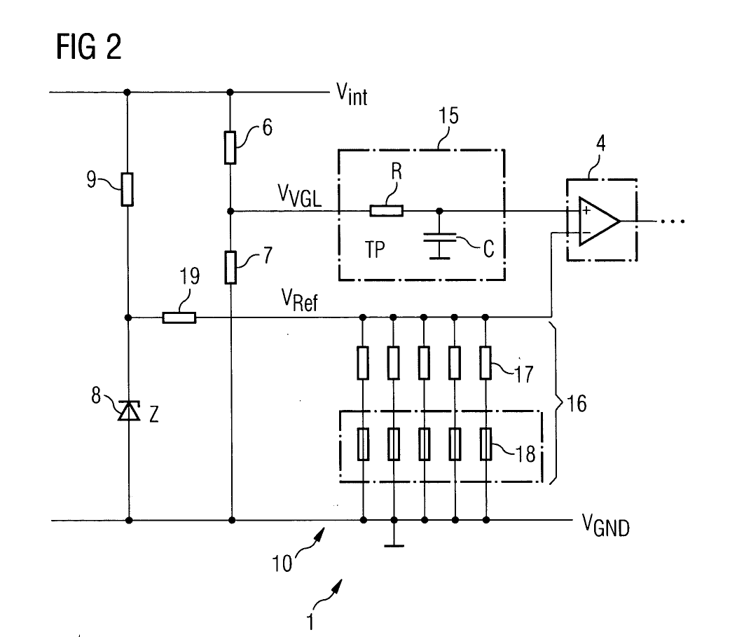

FIG. 2 illustrates a voltage monitoring circuit in accordance with another embodiment of the invention, which generally provides two improvements compared with the voltage monitoring circuit in accordance with FIG. 1.

To prevent momentary reductions of the internal burn-in voltage V_{INT} from immediately leading to an error, a low-pass filter circuit 15 is provided, which buffers momentary voltage dips with respect to the noninverting input of the comparator device 4. The low-pass filter circuit 15 may be formed with a capacitor C and a low-pass filter resistor R in a simple manner that is generally known. Other low-pass filter circuits known in the art are also contemplated.

To make the voltage monitoring circuit 1 adjustable, the fourth resistor element may be embodied in adjustable fashion. For this purpose, the fourth resistor unit 10 has a plurality of resistance paths 16 which are arranged in parallel with one another and are in each case formed with a resistor 17 and a laser fuse element 18. The laser fuse elements 18 may comprise lines which can be severed during a laser trimming process with the aid of a laser beam, depending on whether an electrical connection is intended to be provided. Such laser fuses are provided, for example, to permanently store setting values in an integrated circuit or to replace defective memory areas of an integrated memory circuit by redundant memory areas. The integrated circuit is set after production has been completed, in a so-called laser trimming process.

With the aid of the laser fuse elements 18 of the voltage monitoring circuit, the reference potential V_{Ref} can thus be set together with the setting of further laser fuse elements (not shown) in the integrated circuit. The respective resistance path 16 can thus be left intact or switched off by severing respective laser fuse elements 18. By providing suitable resistances for the resistors 17 of the various resistance paths 16, the resistance of the fourth resistor unit can thus be set selectively, so that the reference potential V_{Ref} can be set selectively by means of the choice of the zener diode 8 and the fifth resistor unit 19 and the fourth adjustable resistor unit 10. The zener diode current is set by means of the third resistor unit 9. Which of the laser fuse elements 18 to be severed is determined according to what threshold is to be prescribed for the internal burn-in voltage V_{INT}.

A further possibility for being able to ascertain functional errors occurring in the integrated circuit from instances when the internal burn-in voltage falls below a desired voltage is that the burn-in voltage undershoot detected by the comparator device 4 can be stored in a latch (not shown) and be interrogated at the end of the burn-in operation in the test method which follows and is performed during the burn-in operation, in order to find out whether the burn-in operation has been carried out in accordance with the specifications.

What is claimed is:

1. An integrated circuit comprising a voltage monitoring circuit for monitoring an internal bum-in voltage provided during a burn-in operation of the integrated circuit, the voltage monitoring circuit comprising:
a voltage generator circuit for providing a reference voltage;
a voltage conversion circuit for providing a comparison voltage which is dependent on the internal burn-in voltage; and
a comparator device connected to compare the comparison voltage and the reference voltage, wherein the comparator device outputs a burn-in signal indicating whether the burn-in voltage lies below or above a voltage threshold defined by the reference voltage.

2. The integrated circuit of claim 1, further comprising:
a test circuit connected to receive the burn-in signal from the comparator device, wherein the test circuit generates an error signal indicating a functional error if the burn-in signal indicates that the internal burn-in voltage lies below the reference voltage, wherein the reference voltage defines a lower limit for thee internal burn-in voltage.

3. The integrated circuit of claim 2, wherein the test circuit comprises a switching device which receives the burn-in signal as control signal and applies the error signal indicating the functional error to an output of the test circuit.

4. The integrated circuit of claim 1, wherein the voltage conversion circuit comprises a voltage divider having a first resistor unit and a second resistor unit.

5. The integrated circuit of claim 4, wherein the voltage conversion circuit further comprises a low-pass filter circuit connected between the voltage divider and an input of the comparator device.

6. The integrated circuit of claim 4, wherein the voltage generator circuit comprises a zener diode and a second voltage divider having a third resistor unit and having a fourth resistor unit.

7. The integrated circuit of claim 6, wherein the fourth resistor unit provides an adjustable resistance.

8. The integrated circuit of claim 7, wherein the fourth resistor unit includes a plurality of resistance paths arranged in parallel, each resistance path being selectively switched on or switched off.

9. The integrated circuit of claim 8, wherein at least one resistance path comprises a resistor and a fuse element connected in series, and wherein the at least one resistance path is selectively switched off by severing the fuse element.

10. A method for monitoring an internal burn-in voltage provided during a burn-in operation in an integrated circuit, comprising:
providing a reference voltage;
providing a comparison voltage which is dependent on the internal burn-in voltage; and
comparing the comparison voltage and the reference voltage to generate a burn-in signal for determining whether the burn-in voltage lies below or above a voltage threshold prescribed by the reference voltage.

11. The method of claim 10, further comprising:
generating an error signal to indicate a functional error if the burn-in signal indicates that the comparison voltage lies below the reference voltage, wherein the reference voltage defines a lower limit for the internal burn-in voltage.

12. The method of claim 11, wherein the error signal is generated by a test circuit comprising a switching device which receives the burn-in signal as a control signal.

13. The method of claim 10, wherein the comparison voltage is provided by a voltage divider having a first resistor unit and a second resistor unit.

14. The method of claim 13, further comprising:
filtering out momentary voltage changes of the comparison voltage utilizing a low-pass filter connected to the voltage divider.

15. The method of claim 13, wherein the reference voltage is provided by a voltage generator circuit comprising a zener diode and a second voltage divider comprising a third resistor unit and a fourth resistor unit.

16. The method of claim 15, wherein the reference voltage may be selected by adjusting an adjustable resistance of the fourth resistor unit.

17. An integrated circuit comprising a voltage monitoring circuit for monitoring an internal burn-in voltage provided during a burn-in operation of the integrated circuit, the voltage monitoring circuit comprising:
a voltage generator means for providing a reference voltage;
a voltage conversion means for providing a comparison voltage which is dependent on the internal burn-in voltage; and
a comparator means for comparing the comparison voltage and the reference voltage, wherein the comparator means outputs a burn-in signal indicating whether the burn-in voltage lies below or above a voltage threshold defined by the reference voltage.

18. The integrated circuit of claim 17, further comprising:
a testing means for generating an error signal indicating a functional error if the burn-in signal indicates that the internal burn-in voltage lies below the reference voltage, wherein the reference voltage defines a lower limit for the internal burn-in voltage.

19. The integrated circuit of claim 16, wherein the voltage conversion means comprises a voltage divider means having a first resistor means and a second resistor means and a low-pass filtering means for filtering out momentary voltage changes of the comparison voltage.

20. The integrated circuit of claim 19, wherein the voltage generator means comprises a zener diode and a second voltage divider means having a third resistor means and a fourth resistor means, wherein the fourth resistor means provides an adjustable resistance.
